(19) United States
(12) Patent Application Publication
(10) Pub. No.: US 2014/0327035 A1
(43) Pub. Date: Nov. 6, 2014

(54) ACTIVE MATRIX TYPE DISPLAY DEVICE

(71) Applicant: Sharp Kabushiki Kaisha, Osaka-shi, Osaka (JP)

(72) Inventor: Ryohki Itoh, Osaka-shi (JP)

(73) Assignee: Sharp Kabushiki Kaisha, saka-shi (JP)

(21) Appl. No.: 14/362,440

(22) PCT Filed: Dec. 4, 2012
(86) PCT No.: PCT/JP2012/081313

§ 371 Date: Jun. 3, 2014

(30) Foreign Application Priority Data
Dec. 6, 2011 (JP) 2011-266863

(51) Int. Cl. H01L 33/36; H01L 27/12

(52) U.S. Cl. CPC H01L 33/36; H01L 27/124
USPC 257/99

(57) ABSTRACT

An active matrix substrate includes a plurality of first lines extending parallel to each other, and a plurality of second lines extending parallel to each other, and crossing the plurality of first lines with an insulation film therebetween. The active matrix substrate also includes a plurality of lead-out lines connecting an end of at least one of the plurality of first lines and the plurality of second lines with a driver, and extending spaced apart from each other in a non-display region, and a plurality of redundant wirings extending along the plurality of lead-out lines with an insulation film therebetween. Each of the plurality of lead-out lines overlaps, in plan view, with an overlapping region of any of the plurality of redundant wirings. Each of the plurality of redundant wirings has a length shorter than an arbitrary one of the plurality of lead-out lines overlapping at the overlapping region.

### TECHNICAL FIELD

The present invention relates to an active matrix type display device.

### BACKGROUND ART

Japanese Patent Laying-Open No. 2006-171672 (PTD 1) discloses a repairable array substrate for a disconnected lead-out line. The array substrate disclosed in PTD 1 includes a substrate having a display region and a non-display region adjacent to the display region, and a plurality of signal lines formed at the display region of the substrate, electrically connected to a plurality of lead-out lines, and receiving a driving signal input from the plurality of lead-out lines.

The array substrate also includes a pixel array formed at the display region of the substrate, receiving a driving signal input from a plurality of signal lines, and a repair section formed at the non-display region of the substrate, insulated from and crossing a plurality of lead-out lines, for repairing, when one of lead-out lines is disconnected, that one lead-out line.

### CITATION LIST

### Patent Document

PTD 1: Japanese Patent Laying-Open No. 2006-171672

### SUMMARY OF INVENTION

### Technical Problem

In the case where a redundant wiring directed to repairing a lead-out line is arranged along the lead-out line, load capacitance is developed between the redundant wiring and lead-out line to cause delay of the signal flowing through the lead-out line. Since the redundant wiring disclosed in PTD 1 is formed equal to or longer in length than the lead-out line, the effect of signal delay on the lead-out line is great.

In view of the foregoing, an object of the present invention is to provide an active matrix type display device that can have signal delay suppressed on a repairable lead-out line.

### Solution to Problem

An active matrix type display device according to the present invention includes an active matrix substrate having a display region and a non-display region that is a region excluding the display region, and a driver mounted on the non-display region in the active matrix substrate. The active matrix substrate includes a plurality of first lines extending parallel to each other at least in the display region, and a plurality of second lines extending parallel to each other at least in the display region, and crossing the plurality of first lines with an insulation film therebetween. The active matrix substrate also includes a plurality of lead-out lines connecting one end of at least one of the plurality of first lines and the plurality of second lines with the driver, and extending spaced apart from each other in the non-display region, and a plurality of redundant wirings extending along the plurality of lead-out lines with an insulation film therebetween. Each of the plurality of lead-out lines overlaps, in plan view, with an overlapping region of any of the plurality of redundant wirings. Each of the plurality of redundant wirings has a length shorter than an arbitrary one of the plurality of lead-out lines overlapping at the overlapping region.

In one aspect of the present invention, the width of the overlapping region in each of the plurality of redundant wirings is not uniform.

According to an aspect of the present invention, each of the plurality of redundant wirings includes a plurality of overlapping regions.

According to an aspect of the present invention, the overlapping region in each of the plurality of redundant wirings is provided so as to protrude from a non-overlapping region excluding the overlapping region.

According to an aspect of the present invention, each of the plurality of redundant wirings has the overlapping region at either end.

According to an aspect of the present invention, each of the plurality of redundant wirings is located so as to be sandwiched between two of the plurality of lead-out lines. The overlapping region in each of the plurality of redundant wirings overlaps with the aforementioned two lead-out lines.

According to an aspect of the present invention, each of the plurality of redundant wirings is located so as to be sandwiched between two of the plurality of lead-out lines. The overlapping region in each of the plurality of redundant wirings overlaps with one of the two lead-out lines.

According to an aspect of the present invention, each of the plurality of lead-out lines includes a projection at a position overlapping with the overlapping region.

According to an aspect of the present invention, the lead-out line is provided lower than the redundant wiring with an insulation film therebetween.

### Advantageous Effects of Invention

According to the present invention, signal delay at a repairable lead-out line can be suppressed.

### BRIEF DESCRIPTION OF DRAWINGS

FIG. 1 is a plan view representing a configuration of an active matrix type display device according to a first embodiment of the present invention.

FIG. 2 is an enlarged view of a portion II in FIG. 1.

FIG. 3 is an enlarged view of a portion in FIG. 2.

FIG. 4 is a partial enlarged view representing a repaired state in the active matrix type display device according to the first embodiment.

FIG. 5 is a partial enlarged view representing a configuration of a first modification of redundant wirings of the first embodiment.

FIG. 6 is a partial enlarged view representing a configuration of a second modification of redundant wirings of the first embodiment.

FIG. 7 is a partial enlarged view representing a configuration of a third modification of redundant wirings of the first embodiment.

FIG. 8 is a partial enlarged view representing a configuration of redundant wirings in an active matrix type display device according to a second embodiment of the present invention.

FIG. 9 is an enlarged view of a portion in FIG. 8.

FIG. 10 is a partial enlarged view representing a configuration of a first modification of redundant wirings according to the second embodiment.

FIG. 11 is a partial enlarged view representing a configuration of a second modification of redundant wirings according to the second embodiment.

FIG. 12 is a partial enlarged view representing a configuration of redundant wirings in an active matrix type display device according to a third embodiment of the present invention.

FIG. 13 is a partial enlarged view representing a configuration of redundant wirings in an active matrix type display device according to a modification of the third embodiment.

FIG. 14 is a partial enlarged view representing a configuration of lead-out lines and redundant wirings in an active matrix type display device according to a fourth embodiment of the present invention.

FIG. 15 is a partial enlarged view representing a configuration of lead-out lines and redundant wirings in an active matrix type display device according to a modification of the fourth embodiment.

### DESCRIPTION OF EMBODIMENTS

An active matrix type display device according to a first embodiment of the present invention will be described hereinafter. In the embodiments set forth below, the same or corresponding elements in the drawings have the same reference characters allotted, and description thereof will not be repeated. Although the expression of upper, lower, left, and right are used in the description of the embodiments for the sake of convenience, these expressions are based on the corresponding drawing, and are not intended to restrict the configuration of the invention.

Although the embodiments will be described based on an example of a liquid crystal panel as the display panel constituting an active matrix type display device, the present invention is applicable to a display device other than a liquid crystal panel such as a microcapsule type electrophoretic electronic paper, organic EL (ElectroLuminescence) display, and organic EL display.

### First Embodiment

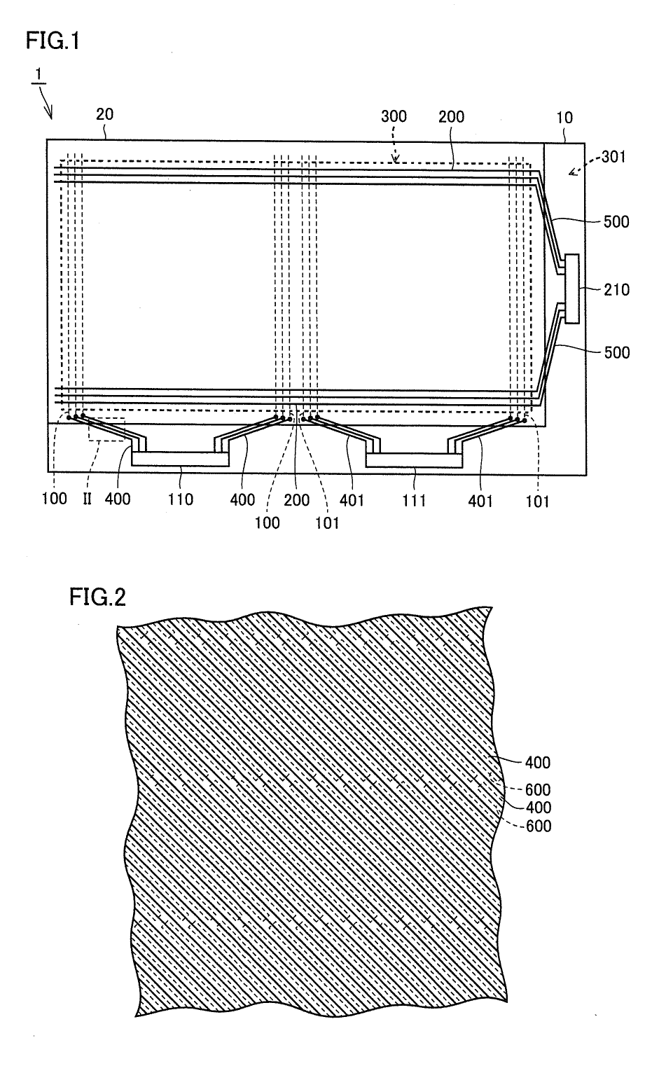

FIG. 1 is a plan view representing a configuration of an active matrix type display device according to the first embodiment of the present invention. In FIG. 1, wiring formed at a gate electrode layer of a TFT is indicated in a solid line, whereas wiring formed at a source/drain electrode layer of a TFT is indicated by a dotted line. In FIG. 1, redundant wiring is not illustrated.

As shown in FIG. 1, an active matrix type display device 1 according to the present embodiment includes an active matrix substrate 10, and a counter substrate 20 facing active matrix substrate 10. Liquid crystal material not shown is located between active matrix substrate 10 and counter substrate 20. Active matrix type display device 1 also includes a driver 50 mounted on active matrix substrate 10.

Counter substrate 20 of the present embodiment has a color filter layer formed, including color filters of red (R), green (G), and blue (B), and a black matrix preventing light leakage between the color filters. Further, a common electrode is formed on the color filter layer.

At active matrix substrate 10, a display region 300 located at substantially the center of active matrix substrate 10, and a non-display region 301 excluding display region 300 are provided. Non-display region 301 is the region of active matrix substrate 10 not facing counter substrate 20 under the state where active matrix substrate 10 and counter substrate 20 are bonded to each other with liquid crystal material not shown therebetween.

At active matrix substrate 10, there are provided a plurality of source lines 100 that are first lines extending parallel to each other at least in display region 300, and a plurality of gate lines 200 that are second lines extending parallel to each other in display region 300, and crossing the plurality of source lines 100 with an insulation film therebetween. The insulation film is formed of a material such as SiN_{X} or SiO_{X}.

In FIG. 1, source lines 100 and gate lines 200 are illustrated only partially. The number of source lines 100 and gate lines 200 is respectively set arbitrarily.

In the present embodiment, the plurality of source lines 100 are provided at display region 300 for each of RGB. In other words, a source line for R, a source line 100 for G, and a source line 100 for B are formed at display region 300. In the case of a monochrome liquid crystal panel, the configuration is not limited thereto.

At display region 300, a storage capacitance line not shown is formed in addition to source lines 100 and gate lines 200. The storage capacitance line is provided at display region 300 so as to be parallel to gate lines 200.

At the crossing region between source lines 100 and gate lines 200, a switching element such as a TFT or MIM (Metal Insulator Metal) not shown, and a pixel electrode (R, G, or B) not shown, connected to the switching element, are formed.

In the present embodiment, three drivers are mounted. The three drivers can be connected by COG (Chip On Glass) for connection to non-display region 301 in active matrix substrate 10.

Specifically, at the bottom left side of the non-display region in active matrix substrate 10 of FIG. 1, a first source driver 110 is mounted, including a driving circuit supplying a signal to some of source lines 100.

Moreover, at the bottom right side of the non-display region in active matrix substrate 10 of FIG. 1, a second source driver 111 is mounted, including a driving circuit to supply a signal to the remaining source lines 100.

Moreover, at the right side of the non-display region in active matrix substrate 10 of FIG. 1, a gate driver 210 is mounted, including a driving circuit supplying a signal to gate lines 200.

Electrical connection is established between first source driver 110 and one end of some of source lines 100 by a plurality of first source lead-out lines 400 that are lead-out lines extending spaced apart from each other at non-display region 301.

Some of source lines 100 and first source lead-out lines 400 are connected such that one source line 100 and one first source lead-out line 400 establish a one-to-one correspondence. The plurality of first source lead-out lines 400 are formed at a gate electrode layer of a TFT.

Electrical connection is established between second source driver 111 and one end of the remaining source lines 100 by a plurality of second source lead-out lines 401 that are lead-out lines extending spaced apart from each other in non-display region 301.

The remaining source lines 100 and second source lead-out lines 401 are connected such that one source line 100 and one second source lead-out line 401 take a one-to-one correspondence. The plurality of second source lead-out lines 401 are formed at the gate electrode layer of a TFT.

In the case where a plurality of first source lead-out lines 400 and a plurality of second source lead-out lines 401 are to be formed at a TFT gate electrode layer, as in the present embodiment, the connection of first source lead-out lines 400 and second source lead-out lines 401 must be changed from the source/drain electrode layer to the gate electrode layer of the TFT.

In this case, first source lead-out lines 400 and second source lead-out lines 401 partially can be protected by a gate insulation film. Accordingly, the occurrence of disconnection at first source lead-out lines 400 and second source lead-out lines 401 can be reduced. Particularly, since external force is apt to be imposed on a region of a lead-out line located at the crossing with the edge of counter substrate 20, the advantage of protecting a lead-out line at that location with an insulation film is great.

Gate driver 210 and the one end of gate lines 200 are electrically connected by a plurality of gate lead-out lines 500 that are lead-out lines extending spaced apart from each other in non-display region 301.

Gate lines 200 and gate lead-out lines 500 are connected such that one gate line 200 and one gate lead-out lines 500 take a one-to-one correspondence. Gate lead-out lines 500 are formed at the gate electrode layer of a TFT.

At active matrix type display device 1 of the present embodiment, a plurality of redundant wirings extend along all of the plurality of first source lead-out lines 400, the plurality of second source lead-out lines 401 and the plurality of gate lead-out lines 500 with an insulation film therebetween.

In other words, lead-out lines that can be repaired by the redundant wiring include first source lead-out lines 400, second source lead-out lines 401 and gate lead-out lines 500. The plurality of lead-out lines may be any of first source lead-out lines 400, second source lead-out lines 401 and gate lead-out lines 500.

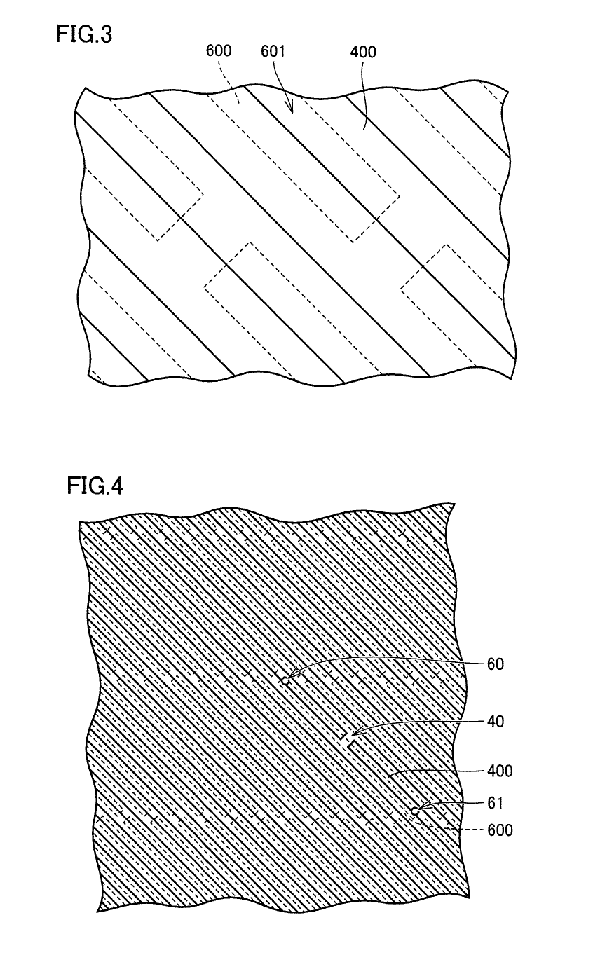

The plurality of redundant wirings extending along first source lead-out lines 400 will be described hereinafter. FIG. 2 is an enlarged view of portion II in FIG. 1. FIG. 3 is an enlarged view of a portion of FIG. 2.

As shown in FIGS. 2 and 3, the plurality of redundant wirings 600 according to the present embodiment are located in a manner shifted in a leftward and downward direction relative to the plurality of first source lead-out lines 400. First source lead-out line 400 and redundant wiring 600 are located alternate with each other.

Each of redundant wirings 600 has an overlapping region 601, corresponding to a portion of redundant wiring 600 in the width direction overlapping with any of first source lead-out lines 400 along redundant wiring 600 entirely in the length direction.

In the present embodiment, a plurality of redundant wirings 600 are provided linearly in an intermittent manner with respect to one first source lead-out line 400. Redundant wirings 600 are formed at the source/drain electrode layer of a TFT. In other words, a plurality of lead-out lines are provided lower than the redundant wirings with an insulation film therebetween. This causes the lead-out lines to be located remote from the outer surface, allowing corrosion and damage to be prevented.

The configuration of first source lead-out lines 400 and redundant wirings 600 is not limited to the configuration set forth above as long as each of first source lead-out lines 400 overlaps with redundant wirings 600 in plan view.

Further, redundant wirings 600 may be formed at the gate electrode layer of a TFT, whereas first source lead-out lines 400, second source lead-out lines 401 and gate lead-out lines 500 may be formed at the source/drain electrode layer of a TFT.

Each of redundant wirings 600 is shorter than the length of an overlapping first source lead-out line 400. In other words, among first source lead-out line 400 and redundant wiring 600 overlapping with each other, redundant wiring 600 is shorter than first source lead-out lines 400. For example, first source lead-out line 400 has a length of 10 mm, whereas redundant wiring 600 has a length of 0.3 mm.

Although the present embodiment has been described based on an example in which redundant wirings 600 are formed of ITO (Indium Tin Oxide), the material of redundant wirings 600 is not limited thereto. For example, IZO (InZnO) or a metal material having light blockage may be employed. Moreover, redundant wiring 600 may be formed of a material identical to that of source lines 100 formed at the same layer. Redundant wirings 600 are preferably covered with a protection film.

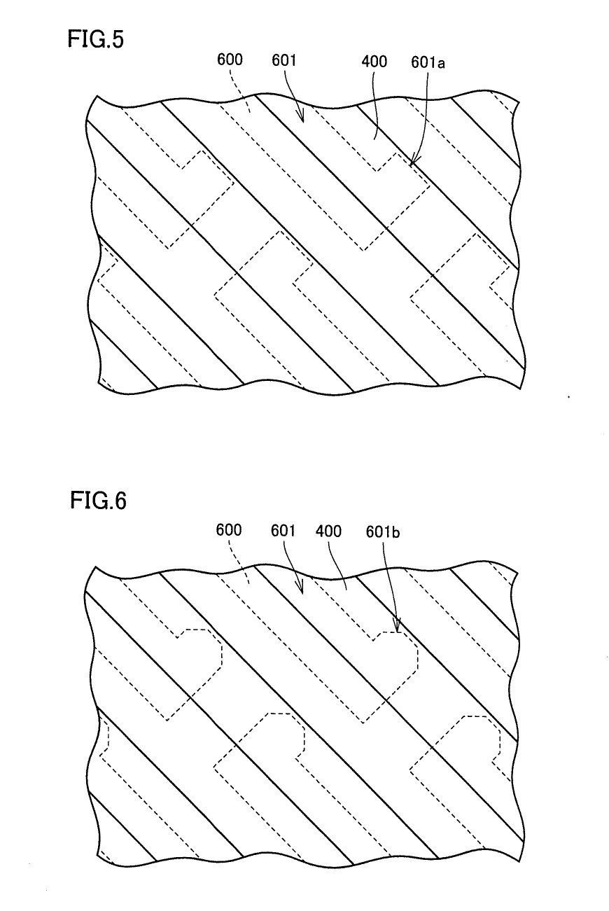

FIG. 4 is a partial enlarged view representing a repaired state in an active matrix type display device according to the present embodiment. FIG. 4 shows an enlargement of the same range as FIG. 2.

As shown in FIG. 4, one end 60 and the other end 61 of redundant wiring 600 in the direction of the length, overlapping with first source lead-out line 400 disconnected at a disconnection 40 is irradiated with a laser beam. By irradiating the overlapping region 601 at either end including one end 60 and the other end 61, the portion of insulation film located at the region therebetween is removed to cause coupling by fusion between first source lead-out lines 400 and redundant wiring 600 to establish electrical connection.

As a result, the signal supplied from first source driver 110 towards first source lead-out line 400 having a disconnection 40 will be transmitted to source line 100 via redundant wiring 600 connected to this first source lead-out line 400.

Since the length of redundant wiring 600 is shorter than first source lead-out line 400, the load capacitance developed between redundant wiring 600 and first source lead-out line 400 can be reduced, as compared to the case where the length of redundant wiring 600 is equal to or greater than the length of first source lead-out line 400. Therefore, signal delay at first source lead-out line 400 can be suppressed.

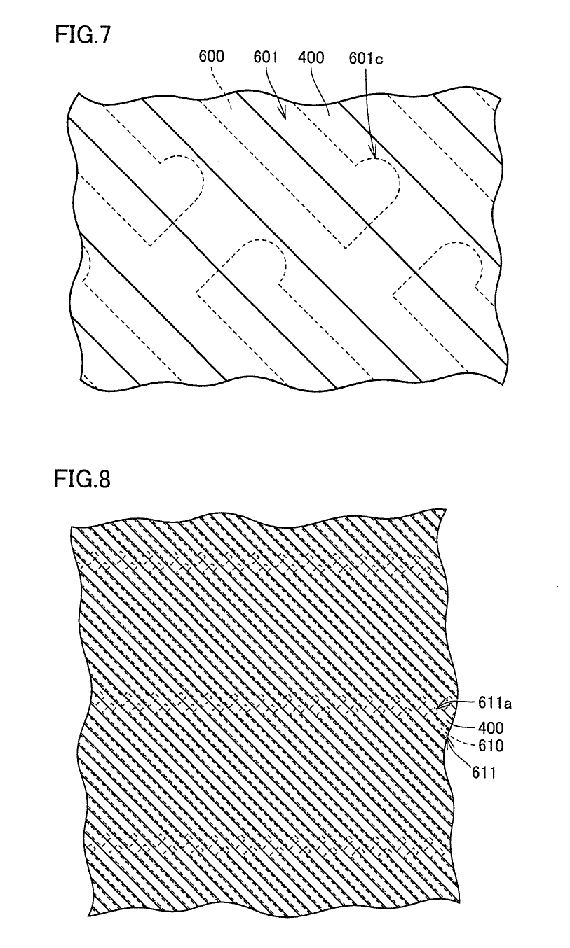

A modification of redundant wirings 600 of the present embodiment will be described hereinafter. FIG. 5 is a partial enlarged view representing a configuration of a first modification of redundant wirings of the present embodiment. FIG. 6 is a partial enlarged view representing a configuration of a second modification of redundant wirings of the present embodiment. FIG. 7 is a partial enlarged view representing a configuration of a third modification of redundant wirings of the present embodiment. FIGS. 5-7 show an enlargement of the same range as FIG. 3.

In the first modification of the present embodiment, the width of the overlapping region of each of redundant wirings 600 is not uniform, as shown in FIG. 5. Specifically, a rectangular enlarged region 601a is provided at overlapping region 601 at both ends of a redundant wiring 600.

In the second modification of the present embodiment, an enlarged region 601b of a hexagonal shape is provided at overlapping portion 601 at both ends of each redundant wiring 600, as shown in FIG. 6. In a third modification of the present embodiment, an enlarged region 601c of a semi-circular shape is provided at overlapping region 601 at both ends of each of redundant wirings 600.

By increasing overlapping region 601 at both ends of redundant wiring 600 as shown in FIGS. 5-7, the radiation target of the laser beam becomes larger, facilitating laser beam radiation control. The location of a wide width of overlapping portion 601 is not limited to either end of redundant wiring 600, and may be at an arbitrary location of redundant wiring 600.

An active matrix type display device according to a second embodiment of the present invention will be described hereinafter. In the active matrix type display device of this embodiment, only the configuration of redundant wirings differs from that of active matrix type display device 1 according to the first embodiment. Therefore, description of other configuration will not be repeated.

### Second Embodiment

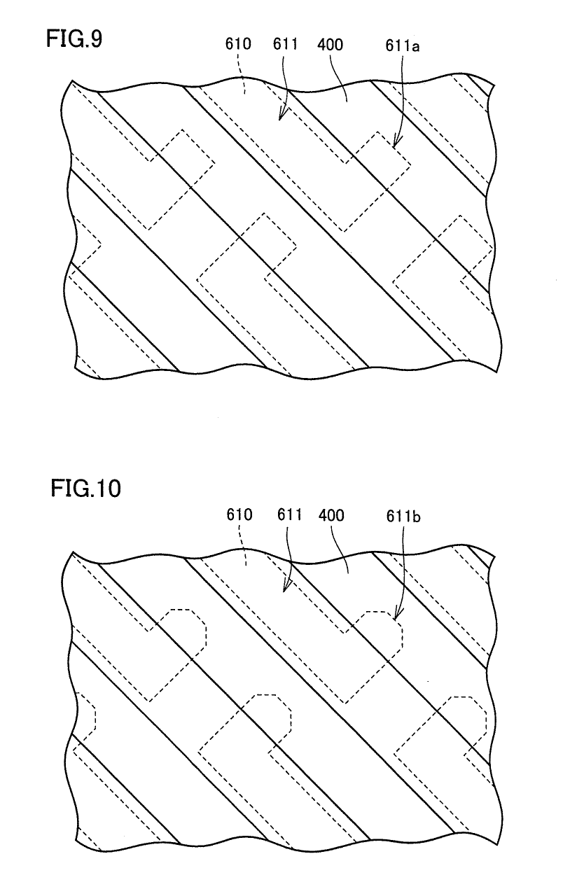

FIG. 8 is a partial enlarged view representing a configuration of redundant wirings in an active matrix type display device according to a second embodiment of the present invention. FIG. 9 is an enlarged view of a portion in FIG. 8. FIG. 8 shows an enlargement of the same range as FIG. 2.

As shown in FIGS. 8 and 9, each of redundant wirings 610 has a plurality of overlapping regions in the active matrix type display device according to the second embodiment of the present invention. In the present embodiment, each of redundant wirings 610 has two overlapping regions 611a. The number of overlapping regions 611a is not limited to two, and may be three or more.

Overlapping region 611a is provided so as to protrude from a non-overlapping region 611 excluding overlapping region 611a. Specifically, an overlapping region 611a of a rectangular shape is provided at either end of redundant wiring 610, overlapping with a first source lead-out line 400.

Since redundant wiring 610 can be shortened by forming two overlapping regions 611a at either end of redundant wiring 610, the load capacitance developed with first source lead-out line 400 can be reduced. The position where overlapping region 611a is located is not limited to either end of redundant wiring 610, and may be at an arbitrary position of redundant wiring 610.

By directing a laser beam to this overlapping region 611a, the insulation film located therebetween is removed, and first source lead-out line 400 and redundant wiring 610 are coupled by fusion to establish electrical connection.

As a result, the signal supplied from first source driver 110 to first source lead-out line 400 having a disconnection 40 will be transmitted to source line 100 through redundant wiring 610 connected to this first source lead-out line 400.

In the present embodiment, the overlapping area between first source lead-out line 400 and redundant wiring 610 is smaller as compared to that in the active matrix type display device of the first embodiment. Therefore, the load capacitance developed between redundant wiring 610 and first source lead-out line 400 can be further reduced. Accordingly, signal delay on first source lead-out line 400 can be further suppressed.

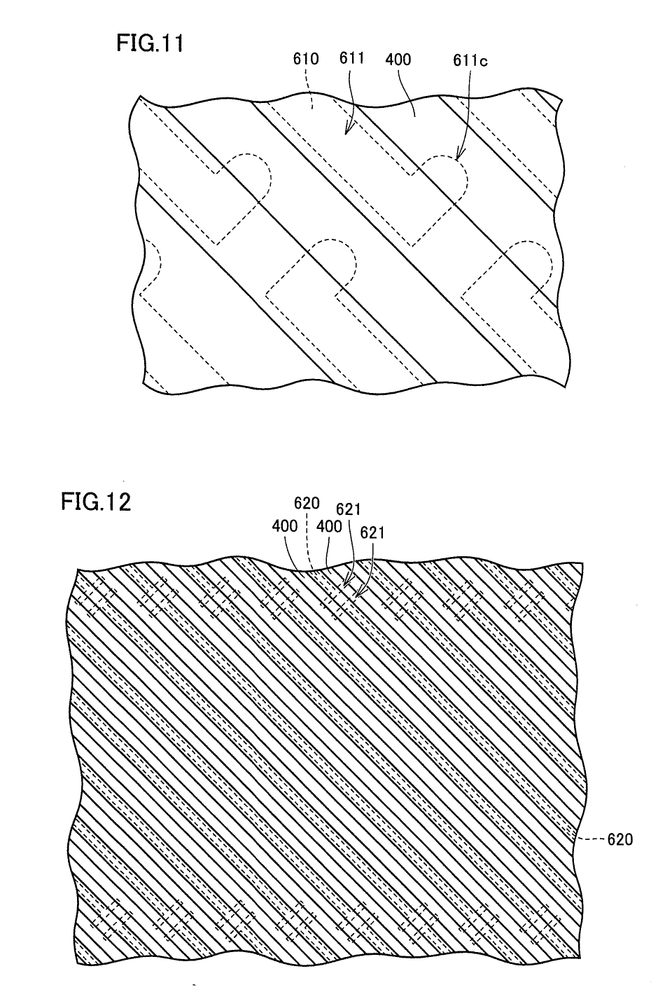

FIG. 10 is a partial enlarged view representing a configuration of a first modification of redundant wirings according to the present embodiment. FIG. 11 is a partial enlarged view representing a configuration of a second modification of redundant wirings according to the present embodiment. FIGS. 10-11 show an enlargement of the same range as FIG. 9.

In a first modification of the present embodiment, an overlapping region 611b has a hexagonal shape, as shown in FIG. 10. In a second modification of the present embodiment, an overlapping region 611c has a semi-circular shape, as shown in FIG. 11. The tip region preferably takes a shape having favorable visual confirmation to facilitate radiation control as the laser beam radiation target.

An active matrix type display device according to a third embodiment of the present invention will be described hereinafter. In the active matrix type display device of this embodiment, only the configuration of redundant wirings differs from that of active matrix type display device 1 according to the first embodiment. Therefore, description of other configuration will not be repeated.

### Third Embodiment

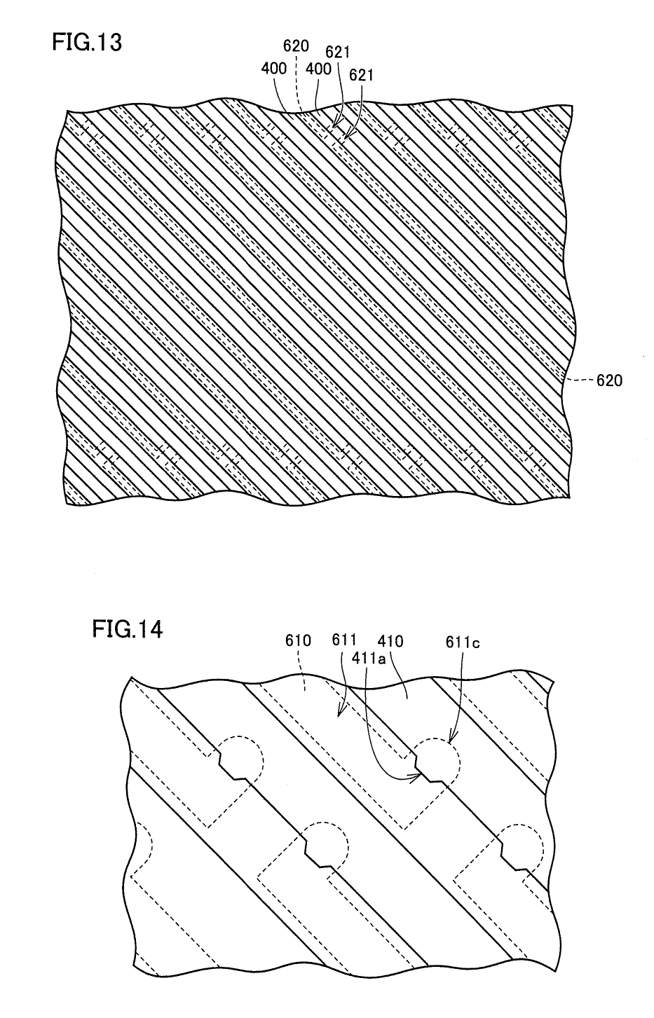

FIG. 12 is a partial enlarged view representing a configuration of redundant wirings in an active matrix type display device according to the third embodiment of the present invention. FIG. 12 shows an enlargement of the same range as FIG. 2

As shown in FIG. 12, at an active matrix type display device according to the third embodiment of the present invention, each redundant wiring 610 is located so as to be sandwiched between two first source lead-out lines 400. An overlapping region 621 of each of redundant wirings 620 overlaps with two first source lead-out lines 400.

Specifically, an overlapping region 621 extending in a direction crossing redundant wiring 620 is provided at either end of redundant wirings 620. This overlapping region 621 overlaps with two first source lead-out lines 400 adjacent to redundant wiring 620. The position where overlapping region 621 is located is not limited to either end of redundant wiring 620, and may be at an arbitrary position of redundant wiring 620.

By directing a laser beam to the region of overlapping region 621 overlapping with the one of first source lead-out lines 400, the insulation film located therebetween is removed, and first source lead-out line 400 and redundant wiring 620 are coupled by fusion to establish electrical connection.

As a result, the signal supplied from first source driver 110 to first source lead-out line 400 having a disconnection 40 will be transmitted to source line 100 through redundant wiring 620 connected to this first source lead-out line 400.

Thus, one of the two first source lead-out lines 400 can be repaired selectively using one redundant wiring 620. Therefore, the number of redundant wirings 620 to be formed can be reduced. Accordingly, the wiring formation step in the fabrication process of an active matrix type display device can be simplified. Moreover, the occurrence of short-circuiting between redundant wirings 620 can be suppressed by increasing the interval between redundant wirings 620.

FIG. 13 is a partial enlarged view representing a configuration of redundant wirings in an active matrix type display device according to the third embodiment of the present invention. FIG. 13 shows an enlargement of the same range as FIG. 2

In the active matrix type display device according to a modification of the present embodiment shown in FIG. 13, an overlapping region 621 in each of redundant wirings 620 overlaps with one of two first source lead-out lines 400. This allows a first source lead-out line 400 that overlaps with overlapping region 621 to be repaired.

An active matrix type display device according to a fourth embodiment of the present invention will be described hereinafter. In the active matrix type display device of this embodiment, only the configuration of redundant wirings differs from that of active matrix type display device 1 according to the second embodiment. Therefore, description of other configuration will not be repeated.

### Fourth Embodiment

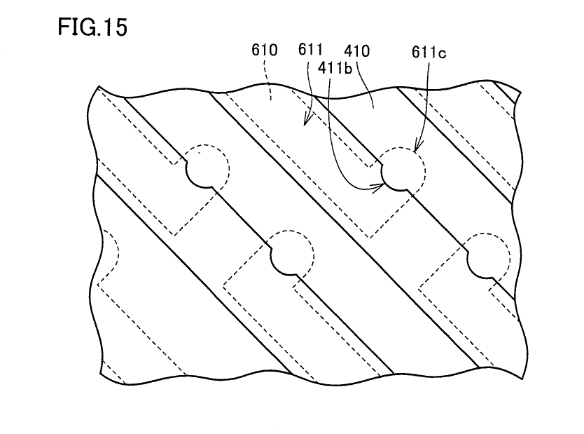

FIG. 14 is a partial enlarged view representing a configuration of lead-out lines and redundant wirings in an active matrix type display device according to a fourth embodiment of the present invention. FIG. 15 is a partial enlarged view representing a configuration of lead-out lines and redundant wirings in an active matrix type display device according to a modification of the present embodiment.

As shown in FIG. 14, each lead-out line in the active matrix type display device according to the fourth embodiment of the present invention includes a projection at a location overlapping with the overlapping region of a redundant wiring. In the present embodiment, a projection 411a of a trapezoidal shape, overlapping with overlapping region 611c of redundant wiring 610, is provided at each of first source lead-out lines 410. In a modification of the present embodiment, a projection 411b of a semi-circular shape is provided, as shown in FIG. 15.

At an active matrix type display device having a resolution not relatively high, the distance between lead-out lines is relatively great. Therefore, the leakage occurrence between lead-out lines can be suppressed at a low level, even in the case where projections 411a and 411b are provided. By providing projections 411a and 411b, the laser beam radiation target is increased to facilitate laser beam radiation control.

Although each of the embodiments set forth above has been described with respect to redundant wirings 600 provided relative to first source lead-out lines 400, a similar advantage can be achieved for a redundant wiring provided relative to second source lead-out lines 401 and gate lead-out lines 500.

It is to be understood that the embodiments disclosed herein are only by way of example, and not to be taken by way of limitation. The scope of the present invention is not limited by the description above, but rather by the terms of the appended claims, and is intended to include any modifications within the scope and meaning equivalent to the terms of the claims.

### REFERENCE SIGNS LIST

1 active matrix type display device; 10 active matrix substrate; 20 counter substrate; 40 disconnection; 50 driver; 60 one end; 61 other end; 100 source line; 110 first source driver; 111 second source driver; 200 gate line; 210 gate driver; 300 display region; 301 non-display region; 400, 410 first source lead-out line; 401 second source lead-out line; 411a, 411b projection; 500 gate lead-out line; 600, 610, 620 redundant wiring; 601, 611a, 611b, 611c, 621 overlapping region; 601a, 601b, 601c enlarged region; 611 non-overlapping region.

1. An active matrix type display device comprising:
an active matrix substrate including a display region and a non-display region that is a region excluding said display region, and
a driver mounted on said non-display region in said active matrix substrate,
said active matrix substrate including
a plurality of first lines extending parallel to each other at least in said display region,
a plurality of second lines extending parallel to each other at least in said display region, and crossing said plurality of first lines with an insulation film therebetween,
a plurality of lead-out lines connecting one end of at least one of said plurality of first lines and said plurality of second lines with said driver, and extending spaced apart from each other in said non-display region, and
a plurality of redundant wirings extending along said plurality of lead-out lines with an insulation film therebetween,
each of said plurality of lead-out lines overlapping, in plan view, with an overlapping region of any of said plurality of redundant wirings,
each of said plurality of redundant wirings having a length shorter than an arbitrary one of said plurality of lead-out lines overlapping at said overlapping region.

2. The active matrix type display device according to claim 1, wherein a width of said overlapping region in each of said plurality of redundant wirings is not uniform.

3. The active matrix type display device according to claim 1, wherein each of said plurality of redundant wirings includes a plurality of overlapping regions.

4. The active matrix type display device according to claim 3, wherein said overlapping region in each of said plurality of redundant wirings is provided so as to protrude from a non-overlapping region excluding the overlapping region.

5. The active matrix type display device according to claim 3, wherein each of said plurality of redundant wirings has said overlapping region at either end.

6. The active matrix type display device according to claim 4, wherein
each of said plurality of redundant wirings is located so as to be sandwiched between two of said plurality of lead-out lines, and
said overlapping region in each of said plurality of redundant wirings overlaps with said two lead-out lines.

7. The active matrix type display device according to claim 4, wherein
each of said plurality of redundant wirings is located so as to be sandwiched between two of said plurality of lead-out lines, and
said overlapping region in each of said plurality of redundant wirings overlaps with one of said two lead-out lines.

8. The active matrix type display device according to claim 1, wherein each of said plurality of lead-out lines includes a projection at a position overlapping with said overlapping region.

9. The active matrix type display device according to claim 1, wherein said lead-out line is provided lower than said redundant wiring with an insulation film therebetween.
